(19) United States
(12) Patent Application Publication
(10) Pub. No.: US 2018/0310440 A1
(43) Pub. Date: Oct. 25, 2018

(54) PRINTED CIRCUIT BOARD ASSEMBLY, AND CORRESPONDING ELECTRONIC DEVICE AND CONSTRUING METHOD

(71) Applicant: THOMSON Licensing, Issy-les-Moulineaux (FR)

(72) Inventors: Mickey Jay HUNT, Camby, IN (US); Randy Wayne CRAIG, FISHERS, IN (US); Theodore Paul CORBIN, INDIANAPOLIS, IN (US); William John TESTIN, INDIANAPOLIS, IN (US); William Philip DERNIER, Indianapolis, IN (US)

(73) Assignee: THOMSON Licensing, Issy-les-Moulineaux (FR)

(21) Appl. No.: 15/769,548

(22) PCT Filed: Oct. 20, 2016
(86) PCT No.: PCT/US2016/057992

§ 371 Date: Apr. 19, 2018

Related U.S. Application Data
(60) Provisional application No. 62/243,859, filed on Oct. 20, 2015.

(51) Int. Cl. H05K 9/00; H05K 1/02

(52) U.S. Cl. CPC H05K 9/006; H05K 9/0033; H05K 1/0216; H05K 2201/09854; H05K 2201/10371; H05K 2201/2072; H05K 2201/0707

(57) ABSTRACT

The present disclosure relates to a printed circuit board assembly including a printed circuit board, a first shielding structure located on a first surface of the printed circuit board and having a first extension element extending from the first shielding structure and through a first hole in the printed circuit board, a second shielding structure located on a second surface of the printed circuit board. According to at least one embodiment on the present disclosure, a first contacting element of the first extension element makes a mechanical and electrical contact between the first shielding structure and the second shielding structure in a contact region entirely located outside the first hole from which the first extension element is extending through.

### CROSS-REFERENCE TO RELATED APPLICATIONS

This application claims the benefit of U.S. Provisional Application Ser. No. 62/243,859, filed Oct. 20, 2015, which is incorporated by reference herein in its entirety.

### 1. TECHNICAL FIELD

The present principles relate generally to printed circuit board and, more particularly, to printed circuit board assemblies having radiofrequency shielding components therein, and corresponding electronic devices and manufacturing methods.

### 2. BACKGROUND ART

The market preference for electronic devices such as set top boxes and the like (e.g. computers, game consoles, DVD players, CD players, etc.) is to have such devices be small, compact, and versatile. However, such preferences increasingly challenge the designers, because set top boxes and the like are required to perform more functions, which require the need for more internal components such as tuners and smart card assemblies in limited interior housing spaces.

Unfortunately, tuners and other components often require shielding within the interior of the housing to shield against radiofrequency interference and/or electrostatic discharge. The introduction of shielding essentially is an additional component which further complicates the designers of such electronic devices.

To appropriately guard at-risk internal components, the common closed polygon vertical wall metal structures or shields have been employed, which are secured generally to a printed circuit board. These have been employed in the high volume manufacturing environments. Some electronic devices of particular interest have satellite receiver functions or data interfaces and include at least one component requiring radiofrequency (RF) interference suppression.

In recent designs, because of consumer demand for smaller devices, the sizes of the circuit boards must decrease resulting in the need for more of the circuit board area to be utilized. This makes it difficult to include some components in the devices such as smartcard connectors, satellite receiver components, system chips, hard drives, user interface components, data interfaces (such as 2.4 Ghz Wi-Fi data interface components to access video in the internet and 5 GHz interface components to transfer video to Wi-Fi Clients).

The difficulty to include some components in the devices such as smartcard connectors in the vicinity of the shield was addressed in the International Application PCT/US2015/34381 having an international filing date of Jun. 5, 2015. The principles in the PCT/US2015/34381 application included a shield design and process that avoids underside processing of the shield and permits underside components such as smartcard assemblies to overlap laterally with the shield. The principles of in the PCT/US2015/34381 are described with reference to FIGS. 1 to 6 and serve as background for the current principles.

FIG. 1 shows an electronic device 1 such as a set top box (STB) or the like having a front wall 2, a rear wall 3, a top 4, and side walls 6 which can be applicable to the present principles. The electronic device 1 can be a set top box or the like such as computers, game consoles, DVD players, CD players, etc. The device can further include a panel jack 5 for connecting cables 9, wherein one of the electrical connectors can be an F-connector 10 or the like. This view with the plurality of cables 9 connected to the electrical connectors on the panel jack 5 is indicative of how crowded the components within the electronic device 1 can be. Such electronic devices 1 which can have a tuner or the like will require a tuner shield or radiofrequency shield. In this view, one of the electrical connectors on the panel jack 5 can be an F-connector 10. Some other connectors on the panel jack 5 can be associated with and connected to other internal components which may require radiofrequency shielding and/or electric discharge shielding.

The electronic device can further include a shielding structure (such as a top shielding structure) comprising a shield 312 (also sometimes known as a “wrap”) and a shield cover 311 for the shield 312 as respectively illustrated by FIG. 2 and FIGS. 3 and 4.

The perimeter of the shield cover 311 can have generally vertical fingers or flaps or spring clips 334 and extend perpendicularly from the peripheral edge of the shield cover, wherein the fingers or flaps or spring clips 334 extend over the exterior sides of the vertical peripheral walls of the shield. The fingers 334 can have edges 335 that bend inward and then outward as they extend from the shield cover to create grasping portion which extends over ribs or engage indents 336 in the vertical peripheral walls of the shield to secure the shield cover to the shield.

As illustrated by FIGS. 3 and 4, the shield 312 can further have interior vertical walls 322 that extend from interior sides of the shield back wall 318, front wall 320, and/or outside vertical sides wall portions 321 and/or other interior vertical walls. The shield 312 can thus include a series of shield rooms made by vertical walls.

As illustrated by FIG. 5, the shield 312 can be attached to the printed circuit board 501 through reflow-soldering. The shield has a contact edge 510 that contacts the circuit board 501 and further has solder tabs, pins or feet 502 extending from the contact edge 510 which are intended to engage corresponding plated through holes at contact points 520 (which can be solder points) on the printed circuit board 501 as shown in FIG. 6. The contact points 520 include the hole and solder that plates the hole.

Depending upon embodiment, the pins or feet 502 can extend only partly into the circuit board (and not extending through the circuit board) or extend through the circuit board. It should be noted that the positioning of the solder pins or feet 502 depends on the requirements of the electronic device and the components therein. Thus, the number and position of the solder pins or feet 502 and corresponding contact points in the printed circuit board 501 can depend and/or be dictated by the wavelengths of the applicable radiofrequency waves.

The shield 312 can be a unitary structure of one folded metal sheet with designed bends and joints, which can be analogous to Origami art in which the solder pins or feet 502 can be formed with the metal sheet. Folded corners 319 (illustrated by FIG. 3) can be present and can increase stability. The folded corners 319 include adjacent vertical wall portions and can include a horizontal wall portion 319H extending from the vertical wall portions.

The shield back wall 318 can be parallel to and adjacent to the vertical chassis rear wall 3, the shield front wall 320 can be opposite the shield back wall 318, and at least two outside vertical side wall portions 321 can extend from the shield back wall 318 to the shield front wall 320. The shield walls can be linear or can have bends. The shield back wall, shield front wall, and outside vertical side wall portions comprise the series of vertical peripheral walls. The proximal portion 316 of the vertical peripheral wall is the back wall 318 and the portions of the outside vertical side wall portions connected to the back wall 318 in proximity of the back wall.

The electronic device can further include a top or shield cover 311 for the shield 312 in which the top or shield cover includes at least three portions: a proximate cover portion 330 that covers the proximal portion or the higher height region 316 of the vertical peripheral walls, a distal cover portion 331 that covers the distal portion 317 of the vertical peripheral walls, and intermediate cover portion 333 that covers the intermediate region 315 of the vertical peripheral walls, wherein the proximal portion 316 transitions to the distal portion 317.

The portions 330, 331, 333 can be planar and the perimeter of the shield cover 311 can have generally vertical fingers or flaps or spring clips 334 and extend perpendicularly from the peripheral edge of the shield cover, wherein the fingers or flaps or spring clips 334 extend over the exterior sides of the vertical peripheral walls which can be understood from FIGS. 2A and 2B. The fingers 334 can have edges 335 that bend inward and then outward as they extend from the top cover to create grasping portion which extends over ribs or engage indents 336 in the vertical peripheral walls to secure the top cover to the shield.

As suggested earlier, FIG. 3 also shows that the shield 312 can include a series of shield rooms (A, B, C, D, E, F, G, H) made by the vertical walls. The shield rooms can be classified as the higher height rooms 313B and the lower height rooms 313A. Both types of rooms 313A, 313B can include interior walls 322 and can be made by the interior walls 322. The shield 312 can be attached to the printed circuit board 501 through reflow-soldering.

In some embodiments, some electronic components (like a smart card assembly which can include a smart card bay and a smart card.) can be positioned in positions overlapping the top shield on the opposite side (or underside) of the printed circuit board. Those other components can laterally overlap the shield and components shielded by the shield 312.

FIG. 6 shows a perspective view of the shield 312 attached to a printed circuit board 501 at contact points 520, which can be solder points. This view shows the soldering or reworking of flat, low or shallow components or second components 504 which can be chip components within the separate shielded wall areas in the lower height rooms 313A by a solder probe, iron or tool 505, wherein these flat, low or shallow components 504 lay lower than the F-connector 10. This view shows how the higher height rooms 313B accommodate the F-connector 10. The F-connector 10 can be considered as a first component at the shield back wall 318.

Experience with the surface-mounted radiofrequency shields has shown that it is difficult to wave-solder along the entire length of the walls of the individual rooms of the shield and testing has demonstrated that only certain critical areas need to be soldered. The proposed principles can for instance involve locating appropriate pin locations on the shield and appropriate mating hole locations in the printed circuit board at the critical points and connecting the pins to the board with solder paste applied by the standard surface-mounted technology which can be a reflow process in the area of the pins to provide a sufficient connection once the assembly has been processed through the reflow oven. Testing has shown the solder pins or feet 502 are ideally about ˜0.8 mm long when the thickness of the printed circuit board is 1 mm (at a soldering perspective). The holes can penetrate through the board and can have a diameter that is only slightly larger in width than the pins to the extent that they must fit the pins and be large enough to account for tolerances in the pin positions so that 100% of the pins in 100% of the assemblies will properly enter the holes. The holes can be elliptically shaped to have the long dimension be 110-200% of the long lateral dimension of the pin such that pins can be easily accommodated when the pins have a flat vertical geometry commensurate with the wall from which they extend. The holes can have the short lateral dimension being larger than the thickness of the shield wall and can be about 110-200% of the short lateral dimension of the pin. If the pins are round, the holes can be round and have a diameter of about 110-200% of the diameter of the pin. The benefit of elliptical shapes for the holes is they permit some limited lateral adjustments or lateral shifting of the pins that are rectangular in shape along the major and minor axis of the ellipses, but they do not permit substantial rotation or twisting of the pins and the shield.

Some additional features which are applicable to the current principle can include reflow-soldering the top shield at solder points at a limited number of specific areas; reflow-soldering the top shield with “over pasting” to increase the amount of solder at only the limited number of locations which can be the critical areas that include the plated holes; reflow-soldering the shield with at least one component that could not be soldered in a wave-solder process, which, for example, can be a tuner F-connector center pin 507 as seen in FIG. 6; reflow-soldering the shield in a designed system that has a component on the side of the circuit board opposite the shield, wherein the “paste-in-hole” process of engaging the pins and hole will not interfere with soldering process, i.e. wave soldering or otherwise, that can be used to attach the components.

The principles which can be include in current principles are intended to include situations in which the solder paste is only applied to hole regions and intended to include other situations in which a wall of solder is needed for performance purposes along some shield walls, but the other shields only require the limited number of contact points 520.

An aspect of the principles which can be used with the current principle includes the method in which an electronic device is constructed. The method is described in FIG. 7 which can begin with providing in step 901 a circuit board 501 having holes 521 and having electronic components on a first side or top side of the circuit board. Next, in step 902 a radiofrequency top shield 312 is formed or provided to surround and provide radiofrequency shielding to the electronic components 504 on the first side of the circuit board. The expressions “to provide” and “providing” in relation to the steps 901 and 902 and in other features that involve components are intended to include making the component, acquiring, or preparing the component for installation. The radiofrequency top shield can have pins 502 and a contact edge 510 from which the pins 502 extend. The pins are positioned to correspond to the holes and can extend from the contact edge a vertical dimension that is between 50 to 90% of a thickness of the printed circuit board. In step 903, at least an interior region of the holes is plated with solder. In step 904, the pins of the radiofrequency top shield are aligned with the holes of the circuit board. In step 905, the radiofrequency top shield is reflow-soldered onto the circuit board in which the pins are engaged with the holes by the solder. In step 906, the pins are inspected to ensure the pins are properly soldered and the electronic components are inspected to ensure that the electronic components are securely attached and/or properly functioning. In step 907, any pins and/or electronic components are touched up by resoldering if more soldering is needed. In step 908, a shield cover 311 is provided or formed and the shield cover is placed on the radiofrequency top shield 312. In step 909, if desired or otherwise designed into the device, another electronic component such as a smart card assembly having a smart card outline (representing the perimeter of the smart card assembly) comprising a is attached on a second side or bottom side of the circuit board such that the smart card outline laterally overlaps at least a portion of the radiofrequency shield 312. In step 910, a chassis or the housing of the electronic device that contains the circuit board and components thereon is closed to complete fabrication of the electronic device.

Although the protocols disclosed in the method above have been quite effective with regards to radiofrequency shielding, class of set top boxes with enhanced features has presented some challenges in term of radiofrequency shielding.

### 3. SUMMARY

The present principles enable at least one of the above disadvantages to be resolved by proposing a printed circuit board assembly comprising a printed circuit board and at least one shielding structure.

According to at least one embodiment of the present disclosure, the printed circuit board assembly comprises:
a first shielding structure located on a first surface of the printed circuit board and having at least one first extension element extending from the first shielding structure and through a first hole in the printed circuit board,
a second shielding structure located on a second surface of the printed circuit board;

According to at least one embodiment of the present disclosure, at least one first contacting element of the at least one first extension element makes a mechanical and electrical contact between the first shielding structure and the second shielding structure in a contact region of said electronic device, said contact region being entirely located outside the first hole from which the at least one first extension element is extending through.

The first and second surfaces can be opposite surfaces of the printed circuit board. For instance, the first shielding structure can be located on a top side of the circuit board and the second shielding structure can be located on a bottom side of the circuit board, or vice-versa. The circuit board can further be equipped with at least one electronic component, notably an electronic component requiring radiofrequency shielding.

According to at least one embodiment of the present disclosure, the second shielding structure has at least one second extension element extending from the second shielding structure and through a second hole in the printed circuit board.

According to at least one embodiment of the present disclosure, the first hole and the second hole are different.

According to at least one embodiment of the present disclosure, at least one adjacent hole of a second hole of the at least one second extension element is a first hole of one of the at least one first extension element.

According to at least one embodiment of the present disclosure, the first and/or second shielding structure comprises a shield and a shield cover.

According to at least one embodiment of the present disclosure, the shield cover of the first and/or of the second shielding structure has anchoring elements for being anchored with the shield of the first and/or of the second shielding structure.

According to at least one embodiment of the present disclosure, the first and/or second shielding structure can be implemented by a single unitary component. The unitary component can comprise for instance a base (acting as a cover) and vertical walls extended from this base (and acting as a shield)

According to at least one embodiment of the present disclosure, the at least one first and/or second extension element is extending from the shield of the first and/or second shielding structure.

According to at least one embodiment of the present disclosure, the mechanical and electrical contact is made by the at least one first contact element and at least one second contact element of the shield cover of the second shielding structure.

According to at least one embodiment of the present disclosure, the mechanical and electrical contact is made by the at least one first contact element and at least one second contact element of the shield of said second shielding structure.

According to at least one embodiment of the present disclosure, at least one second contact element comprises at least one protruding element.

According to at least one embodiment of the present disclosure, the at least one protruding element protrudes in parallel and/or perpendicularly to the at least one first contact element.

According to at least one embodiment of the present disclosure, the at least one first extension element, the at least one second extension element, the at least one first contact element and/or the at least one second contact element comprise at least one element belonging to a group which can include:
a finger;
a foot;
a spring clip;
a spring finger;
a pin;
a rib;
a indent;
a flange;
a wall;
a bead; and/or
a combination thereof.

According to at least one embodiment of the present disclosure, a contact surface of the at least one first contact element has an interior surface contoured to fit over one of said at least one protruding element of said second shielding structure.

According to at least one embodiment of the present disclosure, the first and/or second shielding structure has anchoring elements for anchoring said first and/or second shielding structure to said printed circuit board.

According to at least one embodiment of the present disclosure, an electrical connection between said first shielding structure and said printed circuit board is made at said first hole.

According to at least one embodiment of the present disclosure, said first hole is a plated-thru hole.

According to at least one embodiment of the present disclosure, an electrical connection to the printed circuit board is made at only one of the first hole and the second hole.

For instance, the at least one first hole makes an electrical connection between the first shielding structure and the printed circuit board and no electrical connection is made by the at least one second hole between the second shielding structure and the printed circuit board.

According to at least one embodiment of the present disclosure, an electrical connection between said second shielding structure and said printed circuit board is made at said second hole.

According to at least one embodiment of the present disclosure, no electrical connection is made at said first hole between said first shielding structure and said printed circuit board.

According to another aspect, the present disclosure relates to an electronic device having a printed circuit board and at least one shielding structure.

According to at least one embodiment of the present disclosure, an electronic device have:
a first shielding structure located on a first surface of the printed circuit board and having at least one first extension element extending from said first shielding structure and through a first hole in the printed circuit board; and
a second shielding structure located on a second surface of the printed circuit board.

According to at least one embodiment of the present disclosure, at least one first contacting element of said at least one first extension element makes a mechanical and electrical contact between the first shielding structure and the second shielding structure in a contact region of said electronic device, the contact region being entirely located outside the first hole from which said at least one first extension element is extending through.

According to at least one embodiment of the present disclosure, the electronic device is a set top box.

The circuit board can further have at least one electronic component, notably an electronic component located on the circuit board, for instance an electronic component requiring radiofrequency shielding.

According to at least one embodiment of the present disclosure, said electronic component can belong to a group of components, which can include:
a smartcard component,
a satellite receiver component,
a system chip,
a hard drive component,
a user interface component,
a data interface; and
a combination thereof.

According to at least one embodiment of the present disclosure, the data interface is adapted to access video in the internet.

According to at least one embodiment of the present disclosure, the data interface is adapted to transfer video to at least one Wi-Fi Client.

Depending upon embodiments said first and/or second shielding structure can comprise a single height shield, a multiple height shield and/or a combination thereof.

The electronic device of the present disclosure can be adapted to include a printed circuit board assembly, comprising a printed circuit board and at least one shielding structure, according to any embodiments of the present disclosure.

Furthermore, the present embodiments can be employed in any combination or sub-combination.

According to a first example, some embodiments can involve a second shielding structure having at least one second extension element extending from the second shielding structure and through a second hole in the printed circuit board, the first and the second shielding structure comprising a shield and a shield cover and the at least one first and second extension element extending respectively from the shield of the first and the second shielding structure.

According to a second example, some embodiments can involve a first shielding structure being a unitary structure with a base and verticals walls extendings from this base, a second shielding structure having at least one second extension element extending from the second shielding structure and through a second hole in the printed circuit board, the second shielding structure comprising a shield (or wrap) and a shield cover and the at least one first and second extension element extending respectively from the shield of the first and the second shielding structure.

According to a third example, according to at least one embodiment of the present disclosure, the mechanical and electrical contact is made by said at least one first contact element and at least one second contact element of the second shielding structure, at least one of the at least one first contact elements and/or the at least one second contact element comprising a spring finger.

An aspect of the principles which can be used with the current principle includes a method for construing a printed circuit board assembly, said method comprising:
mounting a first shielding structure on a first surface of a printed circuit board, the first shielding structure having at least one first extension element extending from said first shielding structure and through a first hole in the printed circuit board;
mounting a second shielding structure on a second surface of the printed circuit board; and
at least one first contacting element of the at least one first extension element making a mechanical and electrical contact between the first shielding structure and the second shielding structure in a contact region of said electronic device, said contact region being entirely located outside the first hole from which said at least one first extension element is extending through.

The method of the present disclosure can be adapted to form a printed circuit board assembly, comprising a printed circuit board and at least one shielding structure, according to any embodiments of the present disclosure.

An aspect of the principles which can be used with the current principle includes a method for construing an electronic device, said method comprising:
mounting a first shielding structure on a first surface of a printed circuit board, the first shielding structure having at least one first extension element extending from said first shielding structure and through a first hole in the printed circuit board;
mounting a second shielding structure on a second surface of the printed circuit board; and
at least one first contacting element of the at least one first extension element making a mechanical and electrical contact between the first shielding structure and the second shielding structure in a contact region of said electronic device, said contact region being entirely located outside the first hole from which said at least one first extension element is extending through.

The method of the present disclosure can be adapted to form an electronic device including a printed circuit board and at least one shielding structure, according to any embodiments of the present disclosure.

Furthermore, the present embodiments can be employed in any combination or sub-combination.

### 4. LIST OF DRAWINGS

The present disclosure will be better understood, and other specific features and advantages will emerge upon reading the following description, the description making reference to the annexed drawings wherein:

FIG. 1 shows a perspective rear view of an electronic device that employs at least one radiofrequency shielding structure according to the current principles.

FIGS. 2 et 3 shows perspective views of elements of a shielding structure, comprising a shield cover and a dual height radiofrequency shield that are applicable to the current principles.

FIG. 4 is a top plan view of the dual height radiofrequency shield that is applicable to the current principles.

FIG. 5 shows a perspective view of the dual height radiofrequency shield according to the current principles.

FIG. 6 is a partial perspective view of a printed circuit board assembly comprising a printed circuit board and a top shield soldered to the printed circuit board.

FIG. 7 is a flowchart for a method of forming the electronic device that is applicable to the current principles.

FIG. 8 is a flowchart illustrating a method of forming an electronic device comprising two shielding structures compatible with at least one embodiment illustrated by one of the above figures.

FIG. 9A shows, on the cross section partial view illustrated by FIG. 11A, a ground path between particular points of the top shielding structure and the bottom shielding structure.

FIG. 9B shows, on the cross section partial view illustrated by FIG. 15A, a ground path between particular points of the top shielding structure and the bottom shielding structure.

FIG. 10A shows a cross section partial view, according to a first embodiment, of a circuit board assembly comprising a printed circuit board, a top shielding structure and a bottom shielding structure, the cross section being made at the level of clearance holes of the circuit board, from which extension elements of one of the shielding structures are extending.

FIG. 10B shows a top view of an extension element of the bottom shielding structure extending through a clearance hole of the circuit board illustrated by FIG. 10A.

FIG. 100 shows a partial perspective view of a lateral wall of the top shielding structure equipping the circuit board illustrated by FIGS. 10A and 10B, and the contacts with extension elements of the bottom shielding structure (some extension elements of the bottom shielding structure and some elements for anchoring the cover of the top shielding structure with the shield of the top shielding structure being omitted in the figure).

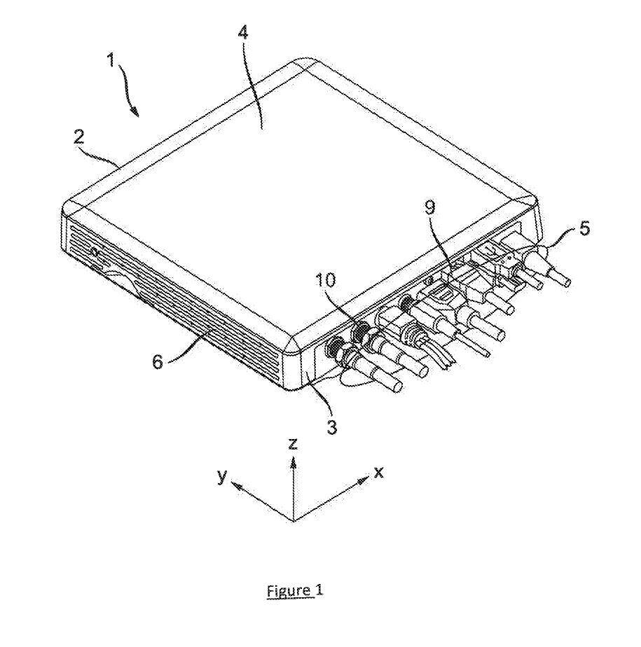

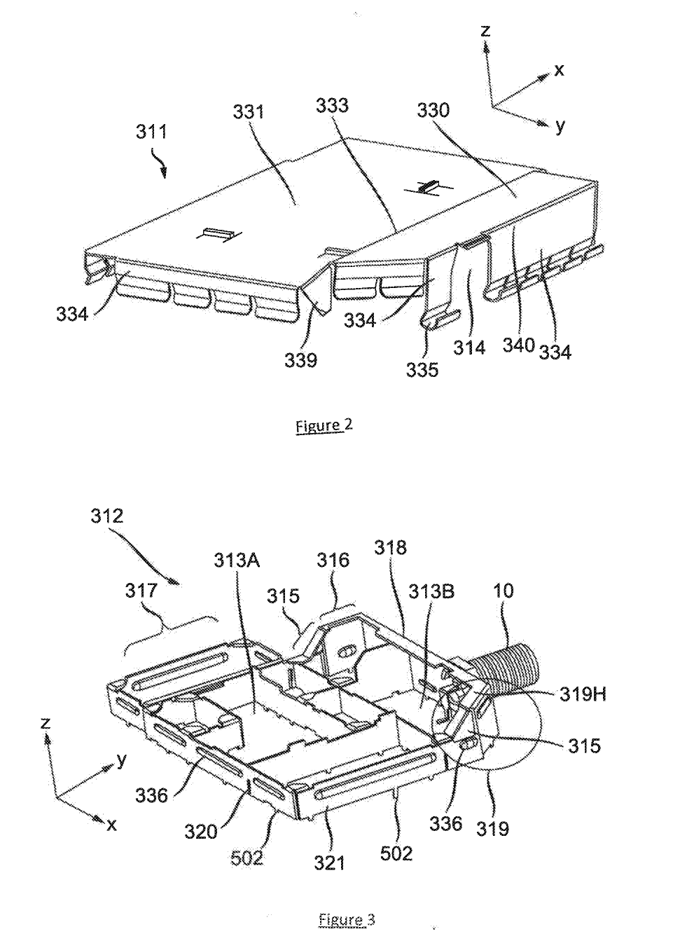

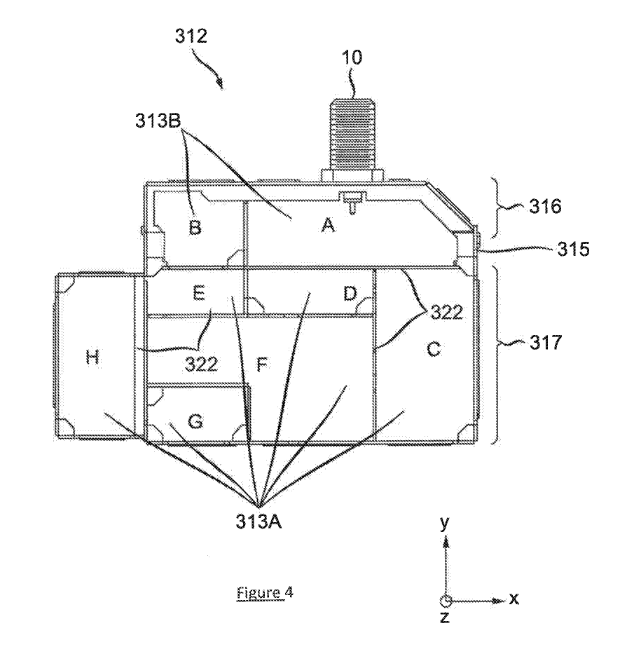

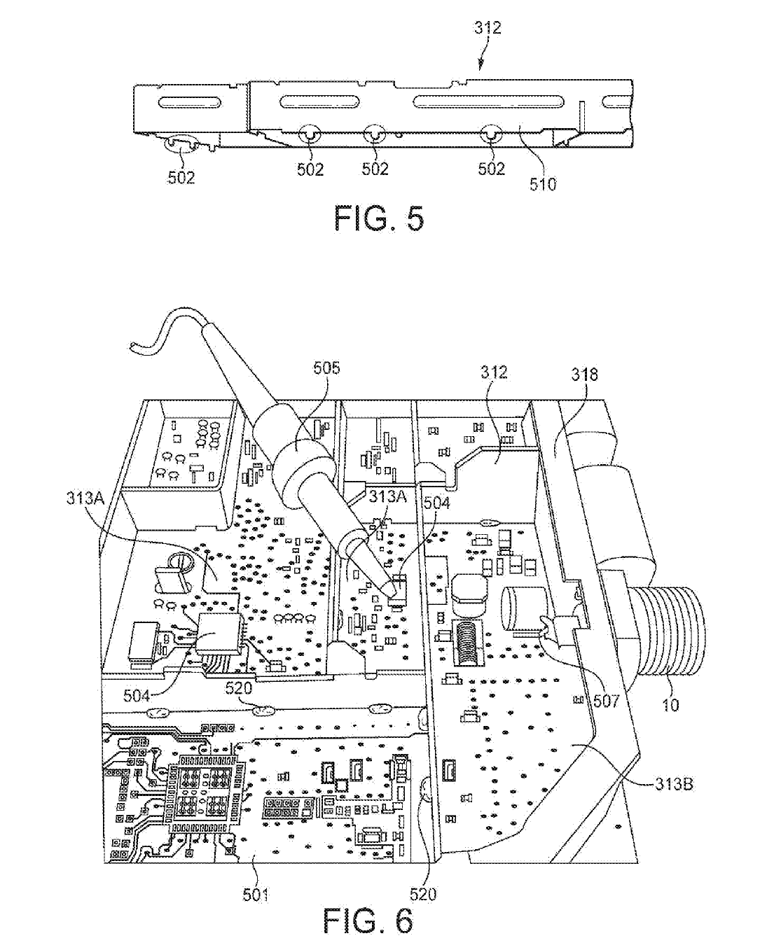

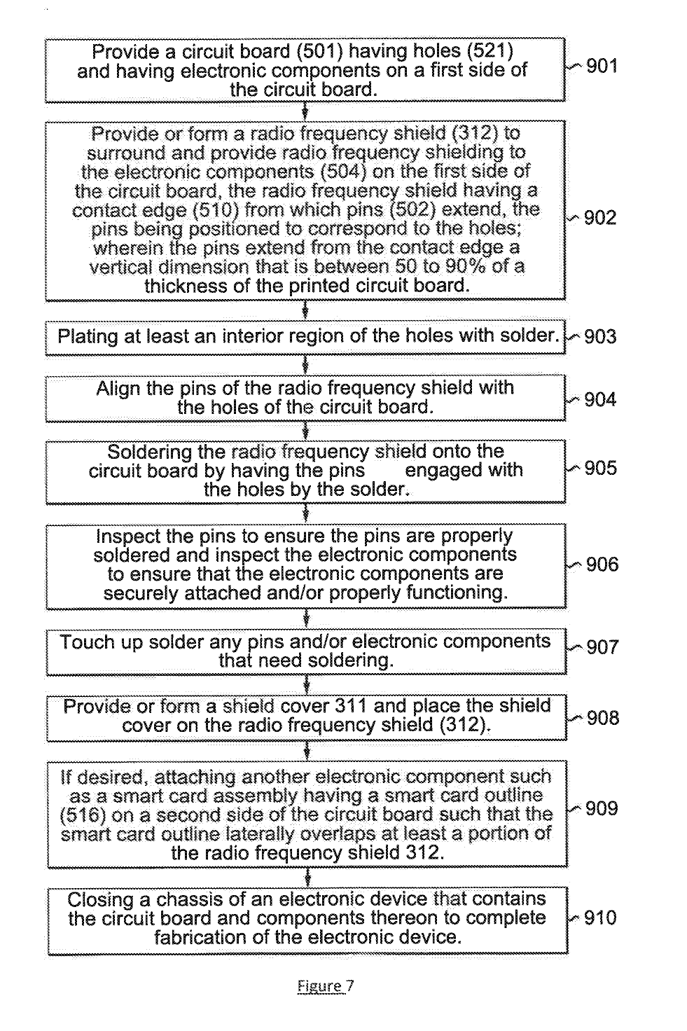

FIG. 11A shows a cross section partial view, according to a second embodiment, of a of a circuit board assembly comprising a printed circuit board, a top shielding structure and a bottom shielding structure, the cross section being made at the level of clearance holes of the circuit board, from which extension elements of one of the shielding structures are extending.

FIG. 11B shows a top view of an extension element of the bottom shielding structure extending through a clearance hole of the circuit board illustrated by FIG. 11A.

FIG. 11C shows a partial perspective view of a lateral wall of the top shielding structure equipping the circuit board illustrated by FIGS. 11A and 11B, and the contacts with extension elements of the bottom shielding structure (some extension elements of the bottom shielding structure and some elements for anchoring the cover of the top shielding structure with the shield of the top shielding structure being omitted in the figure).

FIG. 12A shows a partial perspective view, according to a third embodiment, of a lateral wall of a top shielding structure equipping a circuit board, and contacts with extension elements of a bottom shielding structure further equipping the circuit board (some extension elements of the bottom shielding structure and some elements of the top cover for anchoring the top cover with the top shield being omitted in the figure).

FIG. 12B shows a top view of an extension element of the bottom shielding structure extending through a clearance hole of the circuit board illustrated by FIG. 12A.

FIG. 12C shows details of the lateral wall of FIG. 12A (top cover of the top shielding structure is not illustrated).

FIG. 13A shows a cross section partial view, according to a fourth embodiment, of a of a circuit board assembly comprising a printed circuit board, a top shielding structure and a bottom shielding structure, the cross section being made at the level of clearance holes of the circuit board, from which extension elements of one of the shielding structures are extending.

FIG. 13B shows a top view of an extension element of the bottom shielding structure extending through a clearance hole of the circuit board illustrated by FIG. 13A.

FIG. 13C shows a partial perspective view of a lateral wall of the top shielding structure equipping the circuit board illustrated by FIGS. 13A and 13B, and the contacts with extension elements of the bottom shielding structure (some extension elements of the bottom shielding structure and some elements for anchoring the cover of the top shielding structure with the shield of the top shielding structure being omitted in the figure).

FIG. 14A shows a cross section partial view, according to a fifth embodiment, of a of a circuit board assembly comprising a printed circuit board, a top shielding structure and a bottom shielding structure, the cross section being made at the level of clearance holes of the circuit board, from which extension elements of one of the shielding structures are extending.

FIG. 14B shows a top view of an extension element of the bottom shielding structure extending through a clearance hole of the circuit board illustrated by FIG. 14A.

FIG. 14C shows a partial perspective view of a lateral wall of the top shielding structure equipping the circuit board illustrated by FIGS. 14A and 14B, and the contacts with extension elements of the bottom shielding structure (some extension elements of the bottom shielding structure and some elements for anchoring the cover of the top shielding structure with the shield of the top shielding structure being omitted in the figure).

FIG. 15A shows a partial top view, according to a sixth embodiment, of a circuit board equipped with a bottom shielding structure.

FIG. 15B shows details of FIG. 15A, illustrating the anchoring of the top shield of the top shielding structure with the bottom shielding structure thanks to support pins.

FIG. 15C shows extension elements of the bottom shielding structure extending through the printed circuit board illustrated by FIG. 15A.

FIG. 15D shows a perspective view of a top shield, before its assembly with the circuit board and the bottom shielding structure of FIGS. 15A and 15B.

FIG. 15E shows cross section partial view, of the circuit board of FIG. 15A, the cross section being made at the level of clearance holes of the circuit board, from which extension elements of top shield are extending (the cover of the top shielding structure is not illustrated).

FIG. 16A shows a partial perspective view, according to a seventh embodiment, of a of a circuit board assembly comprising a printed circuit board, a top shield of a top shielding structure (top cover not being illustrated) and a bottom shielding structure and comprising clearance holes from which extension elements of the top shielding structures are extending, and a side of a lateral wall of the top shield of the top shielding structure.

FIG. 16B shows a top view of an extension element of the bottom shielding structure extending through a clearance hole of the circuit board illustrated by FIG. 16A.

FIG. 16C shows details of the opposite side (compared to the side of the lateral wall illustrated by FIG. 16A) of the lateral wall of the top shield equipping the circuit board illustrated by FIGS. 16A and 16B, and contacts with extension elements of the bottom shielding structure (some extension elements of the bottom shielding structure being omitted in the figure).

FIG. 17A shows a cross section partial view, according to an eight embodiment, of a of a circuit board assembly comprising a printed circuit board, a top shield of a top shielding structure (top cover not being illustrated) and a bottom shielding structure, the cross section being made at the level of clearance holes of the circuit board, from which extension elements of one of the shielding structures are extending.

FIG. 17B shows a top view of an extension element of the bottom shielding structure extending through a clearance hole of the circuit board illustrated by FIG. 17A.

FIG. 17C shows a partial perspective view of the circuit board illustrated by FIGS. 17A and 17B, comprising clearance holes from which extension elements of the top shielding structure are extending, and a side of a lateral wall of the top shield of the top shielding structure equipping the circuit board.

FIG. 17D shows a detailed view of the circuit board of FIG. 16A, the opposite side (compared to the side of the lateral wall illustrated by FIG. 16A) of the lateral wall of the top shield equipping the circuit board and contact between contacting elements of the top shield and contacting element of the bottom shielding structure of FIG. 17A (some extension elements of the bottom shielding structure being omitted in the figure).

FIG. 18A shows a cross section partial view, according to a ninth embodiment, of a of a circuit board assembly comprising a printed circuit board, a top shield of a top shielding structure (top cover not being illustrated) and a bottom shielding structure, the cross section being made at the level of clearance holes of the circuit board, from which extension elements of one of the shielding structures are extending.

FIG. 18B shows a top view of an extension element of the bottom shielding structure extending through a clearance hole of the circuit board illustrated by FIG. 18A.

FIG. 18C shows a partial perspective view of the circuit board illustrated by FIGS. 17A and 17B, comprising clearance holes from which extension elements of the top shielding structure are extending, and a side of a lateral wall of the top shield of the top shielding structure equipping the circuit board.

FIG. 18D shows a detailed view of the circuit board of FIG. 16A, the opposite side (compared to the side of the lateral wall illustrated by FIG. 16A) of the lateral wall of the top shield equipping the circuit board and contact between contacting elements of the top shield and contacting element of the bottom shielding structure of FIG. 18C.

### 5. DESCRIPTION

The present principles relate to circuit boards equipped with shielding structure, and adapted to be mounted in electronic products requiring a better shielding like some set top boxes (STB), which can belong to certain potential product lines of the Applicant. Such products can include at least one smartcard connector, at least one satellite receiver component, at least one satellite receiver, at least one system chip, at least one hard drive and at least one user interface. The products can also include at least one wireless data interface component, like a Wi-Fi interface component. For instance, a STB can include a 2.4 GHz Wi-Fi data interface to access video in the internet and/or a 5 GHz interface to transfer video to Wi-Fi Clients. In some embodiments, the data interface can be located in the same physical module as the other components. This design is different from the design of previous set top boxes that have had 2.4 GHz and 5 GHz data interfaces. Indeed, in such previous STB, the more critical Access Point functions such as source for Wi-Fi video to clients had been performed using a separate module.

The present disclosure proposes several embodiments that help addressing the enhance Radio Frequency shielding needs within this new class of set top boxes. This new class can be characterized in that top and bottom shielding structure in the same general lateral vicinity is needed. For the radiofrequency shielding to be efficient, a mechanical and electrical contact between both shielding structures is needed. In the illustrated embodiments, at least one of the shielding structure comprises extension elements (like pins, or feet) that extends through mating holes of the printed circuit board. The mechanical and electrical contact with both shielding structures is performed outside the mating holes.

Indeed, to meet the combined requirements of the standard STB functions in addition to the requirements of the “Access Point,” the memory speeds of the system chip components of such STB have need to increase. Notably, the system chip can notably use a memory with Double Data Rate (DDR) speed like a memory known as Double Data Rate 4th generation Synchronous Dynamic Random Access Memory (DDR4). The present DDR4 data rate is 2400 MHz which coincides with the frequency of the 2.4 GHz Wi-Fi. The doubling of the DDR4 rate at 4800 MHz falls very close to the 5 GHz Wi-Fi frequency.

New EMI (electromagnetic interference) challenges have appeared when the 5 GHz Access Point function within set top boxes is very close to a high powered (Silicon On Chip component (SOC technology). Those constraints can be more severe than some regulatory constraints imposed by an Official Organization. (Like the Federal Communications Commission (FCC) in the United States). As an example, the sensitivity of Wi-Fi receivers can generate an EMI constraint being more severe than the limit of emissions imposed by the Federal Communications Commission (FCC) of the United States. In order to address the issue of de-sensing the Wi-Fi receiver with clock harmonics from the Silicon On Chip (SOC), better shielding is needed.

It has been determined that in order to minimize the 2400 MHz EMI from the DDR, the spacing between pins 502 (“feet”) of the radiofrequency shield must be kept less than 1/10 the wavelength of the applicable electromagnetic radiation. At ˜5500 MHz, the wavelength is 984/5500=0.18 feet or 2.15 inches and 1/10 of the wavelength is then 0.215 inches or 5.26 mm. Therefore, the distance between the feet on the shield needs to be less than 5.26 mm. As illustrated by FIG. 15D, for the radiofrequency shield, the center-to-center spacing 6040 of the extension elements (like the illustrated pins or feet for instance) 604 is needed to be kept to ˜5.8 mm to guarantee an opening 6042 between two consecutive extension elements 604 is less than 5.26 mm.

Unlike previous STB designs that only shielded the DDR memory on one side of a printed circuit board (for instance a top side), the 2400 MHz DDR data rate forces the shielding, on the other side of the printed circuit board (for instance a bottom side), of the bottom area of the SOC and DDR components as well. Thus, another solution that the “paste-in-hole” design previously used for the mounting of the topside shield is needed for the bottom side shield. Indeed, such a solution does not work on the bottom side. As there being insufficient surface tension between the PCB and the bottom side shield when after reflow soldering the bottom shield, the board is flipped over and the topside shield needs reflow soldered. In the topside reflow operation, the bottom side shield dropped away from the board which reduced its effectiveness as a shield.

Different exemplary embodiments, that can help resolving at least some issue encountered by prior art solutions are described hereinafter. They relate to a printed circuit board 501 equipped with at least two shielding structures. In the illustrated embodiments, the printed circuit board comprises a top shielding structure located above the circuit board, and a bottom shielding structure located under the circuit board, in the same lateral vicinity. Each shielding structure can comprise at least one shield (also called sometimes wrap) and/or at least one shield cover for this shield. Depending upon embodiments, a shield and its shield cover can be implemented by two distinct mechanical modules (or components) or belongs to a same unitary component. The bottom shielding structure is illustrated by figures as a unitary structure (comprising for instance a base part and walls extending for that base part) for simplification purpose. However, it is to be underlined that the bottom shielding structure can be a structure comprising several components, notably a bottom shield and a bottom shielding cover. Notably, in some embodiments, the way the bottom shield cover is mounted with the bottom shield can be performed similarly to what it is described for the top shield cover and the top shield. In such embodiments, the bottom shield and the bottom shield cover can comprise anchoring means, adapted for the assembly of the bottom shield and the bottom shield cover and similar to similar to the anchoring means described in link with the assembly of the top shield and the top shield.

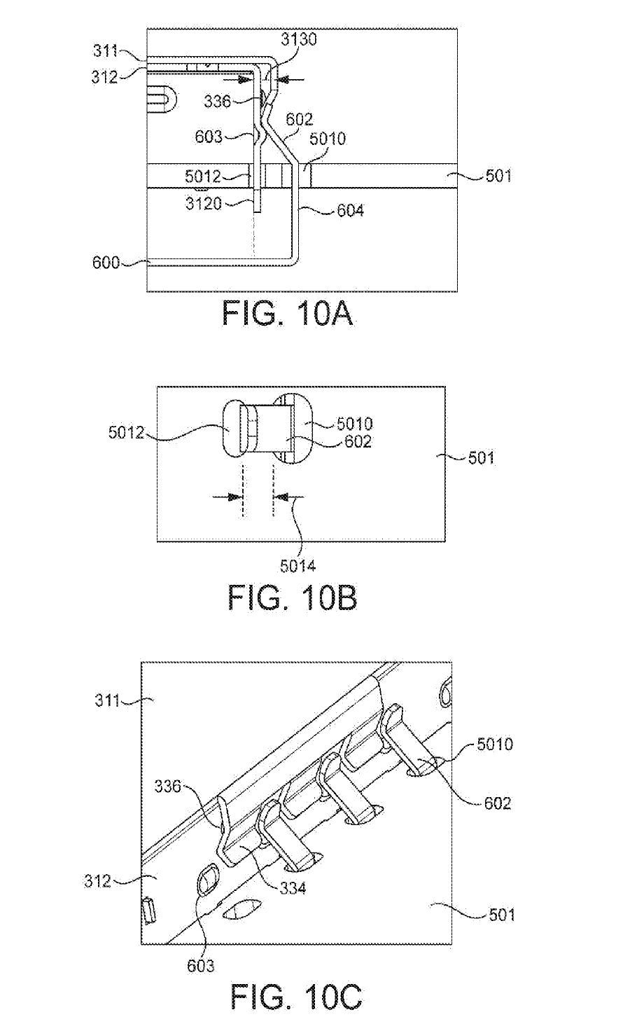

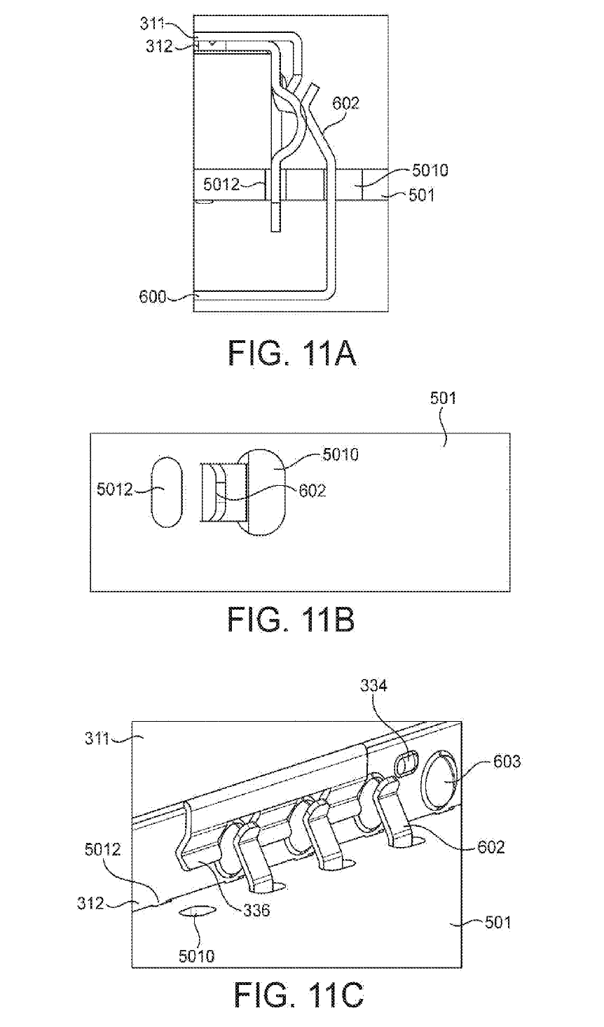

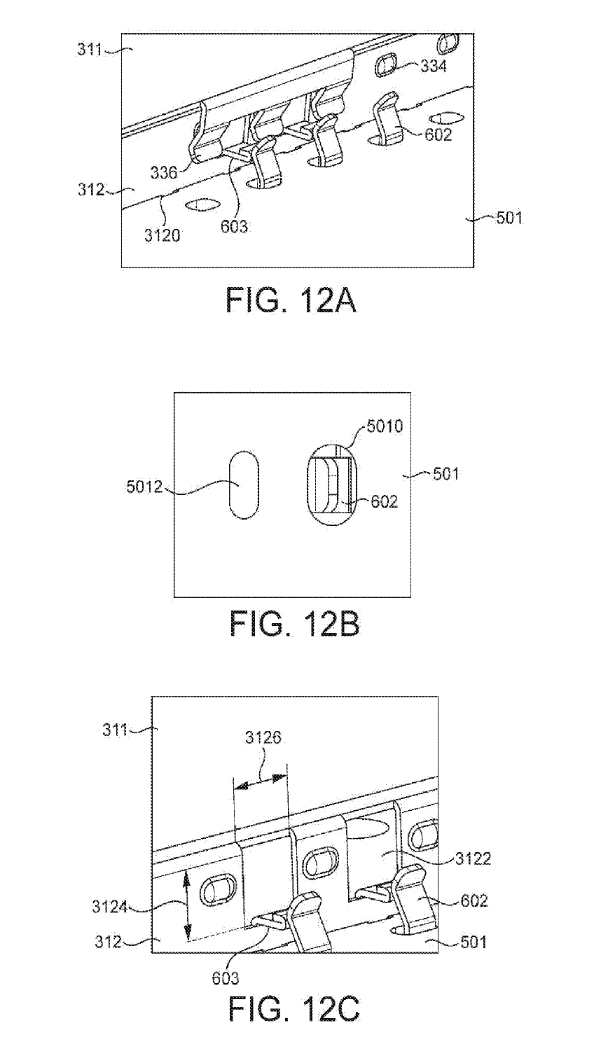

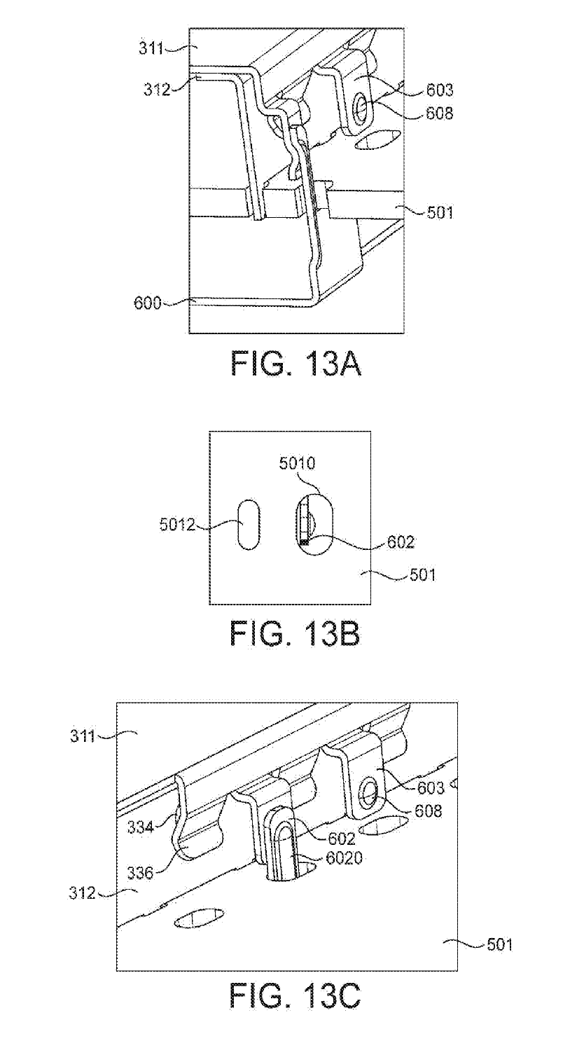

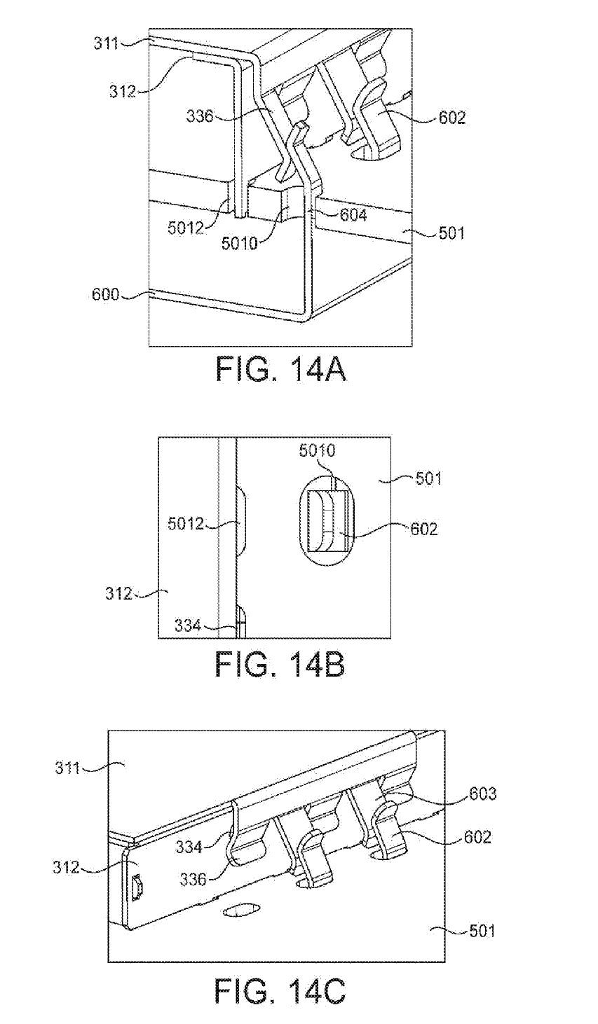

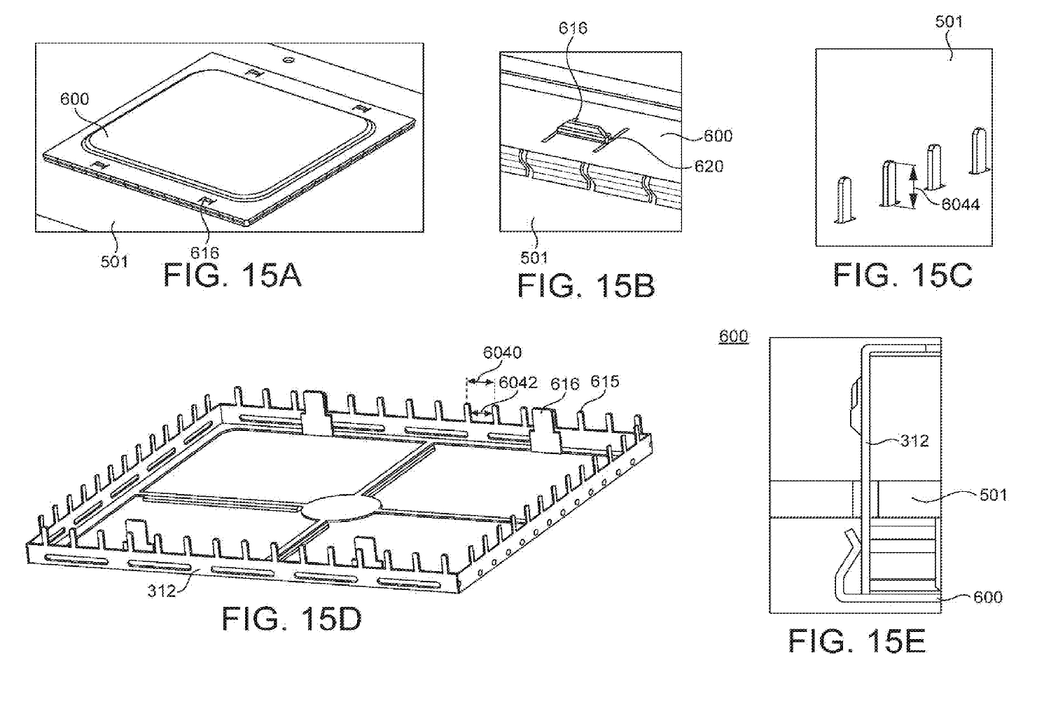

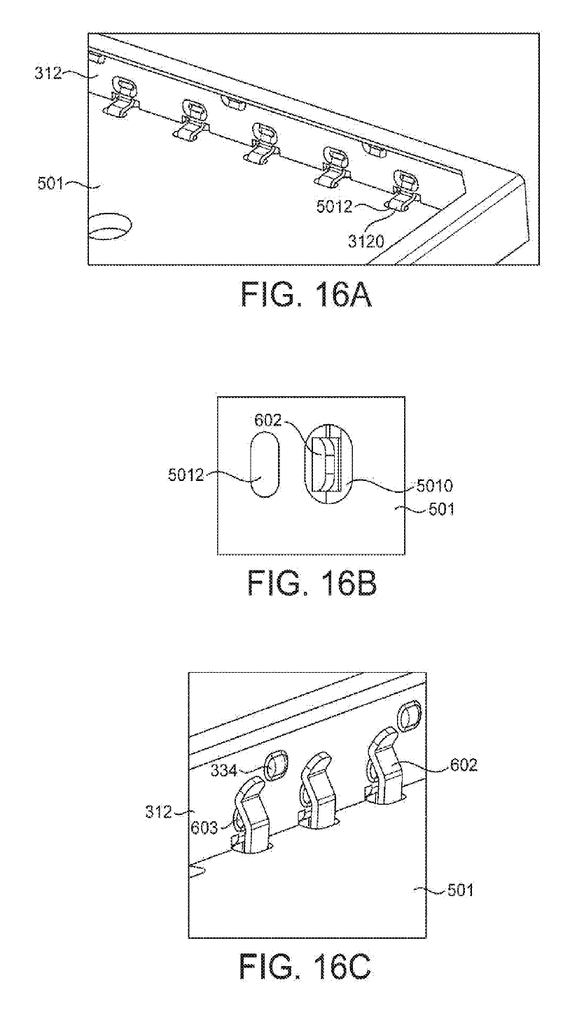

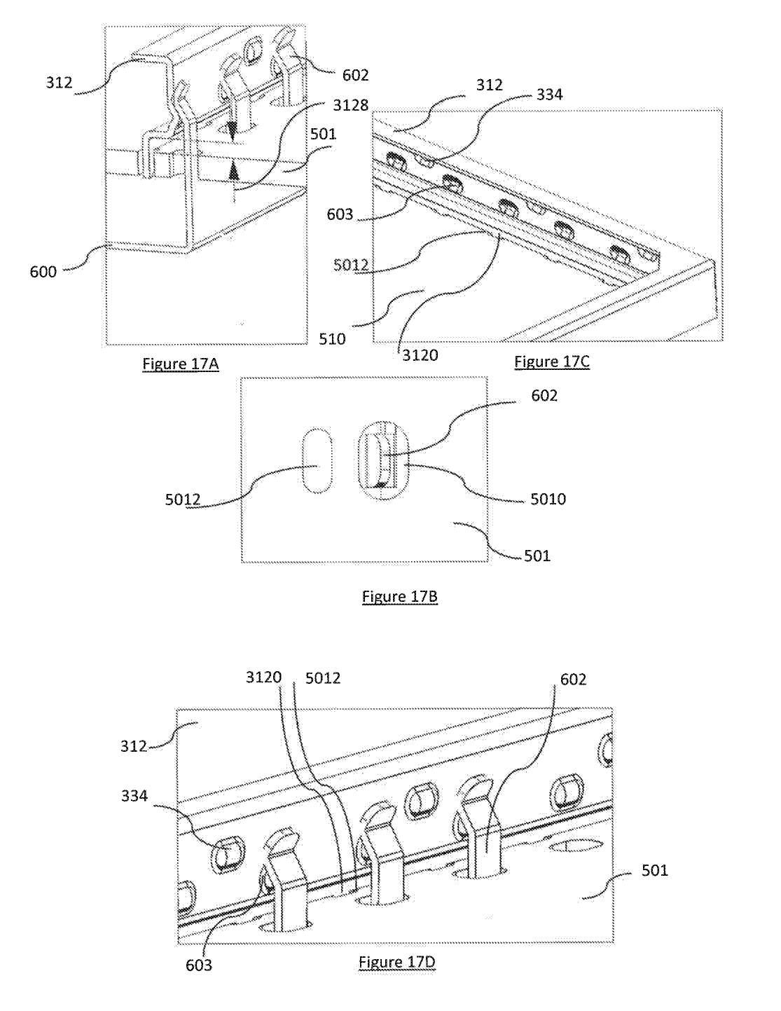

According to a first embodiment illustrated by FIGS. 10A, 10B and 10C, the bottom shielding structure 600 comprises extension elements 604, which extend through a first series of mating holes 5010 of the circuit board 501.

In the particular embodiment illustrated by FIGS. 10A and 10B, the top shield 312 of the top shielding structure also comprises extension elements 3120 (like pins) that extend through a second series of mating holes 5012 of the circuit board. It is to be pointed out that the first and the second series of mating holes 5010, 5012 are different. Notably, a hole 5010, 5012 is used by zero or one extension element (being either an extension element of the top shielding structure, or an extension element of the bottom shielding structure). Both series of holes 5010, 5012 can have different dimensions. Notably, holes 5010 of the first series, used for the bottom extension elements 604 extending from the bottom shielding structure can have a diameter larger than holes 5012 of the second series. Depending upon embodiments, the first and second series can be aligned together (with an alternate design for instance as it will be described below in link with FIGS. 18A to 18D), or can be located parallel of the circuit board, as illustrated by FIG. 10A, 10B or 100. In such a case, the distance 5014 between a hole 5010 of the first series and a hole 5012 of the second series can differ upon embodiments. For instance, the distance between border of holes 5010, 5012 (or in other embodiments the distance between centers of holes 5010, 5012) can be a gap 5014 of 1.2 to 1.8 mm, like a gap of 1.5 mm as illustrated by the distance 5014 of FIG. 10B. Having a gap of least 1.5 mm can help avoiding the risk of breaking of the circuit board during the piercing of the holes. The distance between a hole of the first series and a hole of the second series can notably be chosen in order to respect a distance between pins of both shielding structures taking account of the frequency of the Wi-Fi receiver(s) of the STB, as explained above.

As illustrated by FIGS. 10A and 10B, the extension elements 604 of the bottom shielding structure 600, comprise contacting elements 602 (for instance spring clips as illustrated) that engages with contacting elements 603 (like lower ribs or indents as illustrated) of the top shielding structure. In the illustrated embodiment, the contact elements 603 are located on a lateral wall of the shield 312 of the top shielding structure. In the illustrated embodiment, the top shielding structure is assembled by engaging spring clips 334 of the shield cover 311 of the top shielding structure over upper ribs or indents 336 present on a lateral wall of the shield 312. In the exemplary embodiment of FIG. 10A, a gap 3130 (for instance a gap of 0.5 mm) is present in the top shielding structure between the shield cover and the shield. The upper ribs or indents 336 and the lower ribs or indents 603 can notably be located on a same lateral wall of the shield 312 of the top shielding structure, as illustrated by FIG. 10A. Depending upon embodiments, The upper ribs or indents 336 and the lower ribs or indents 603 can have various height. For instance, the lower ribs can have a height between 0.2 to 1.2 mm (for instance a height of 0, 25 mm).

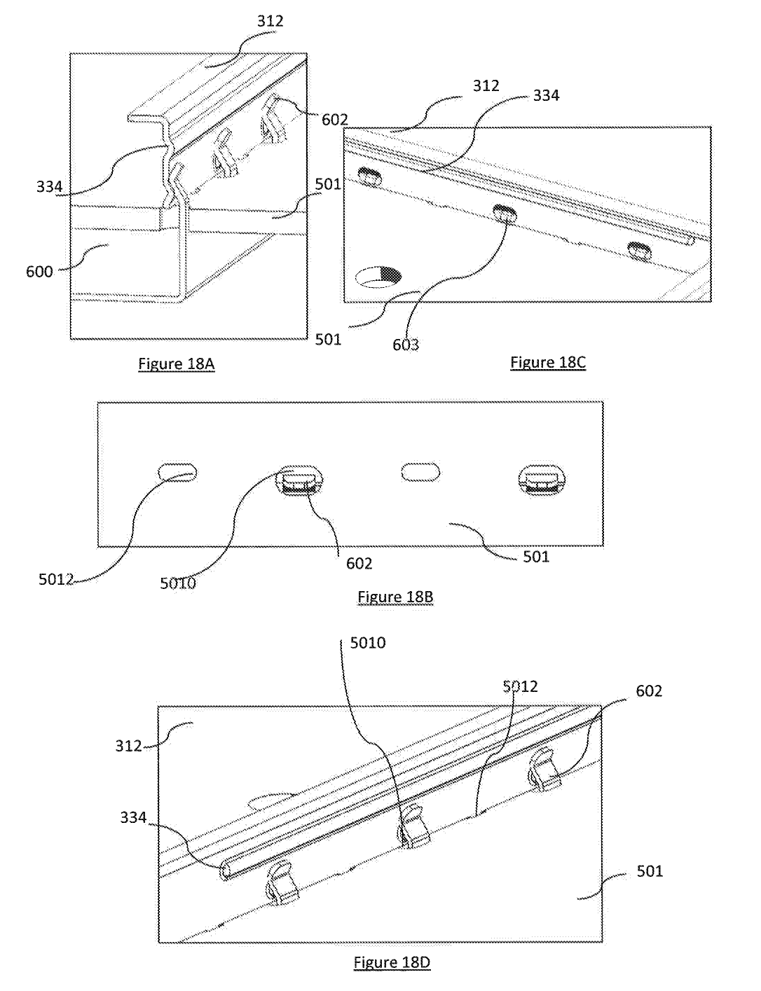

FIGS. 11A, 11B and 11C illustrate a second embodiment similar to the embodiments illustrated by FIGS. 10A to 100, except that the contacting elements of the top shielding structure are lower ribs bigger than in the first embodiment (for instance, lower ribs having a height of 1 mm), and thus the extension elements of the bottom shielding structure are less bended and/or shorter than in the first embodiment, as shown by FIG. 11C. Such an embodiment can permit to reduce the manufacturing cost of the bottom shielding structure (as less material is needed). It is to be noted that the angle formed by the both extremities of a finger 602 (or spring clip) can vary upon embodiments. Notably the angle can belong to a range from 30 degree to 160 degree, for instance the finger can be a 90 degree finger.

The embodiment illustrated by FIGS. 11A to 11C can also permit to use smaller clearance holes and thus to optimize the contact between the circuit board and the bottom shielding structure (and thus help getting a better shielding).

According to this second embodiment, the extremity of a contacting element 602 of an extension element (like the illustrated spring clips) outside the rim of the mating hole 5010 of the circuit board 510 can have a gap of less than 1 mm, for instance a gap between 0.8 to 0.9 mm (like a gap of 8.6 mm) with this rim.

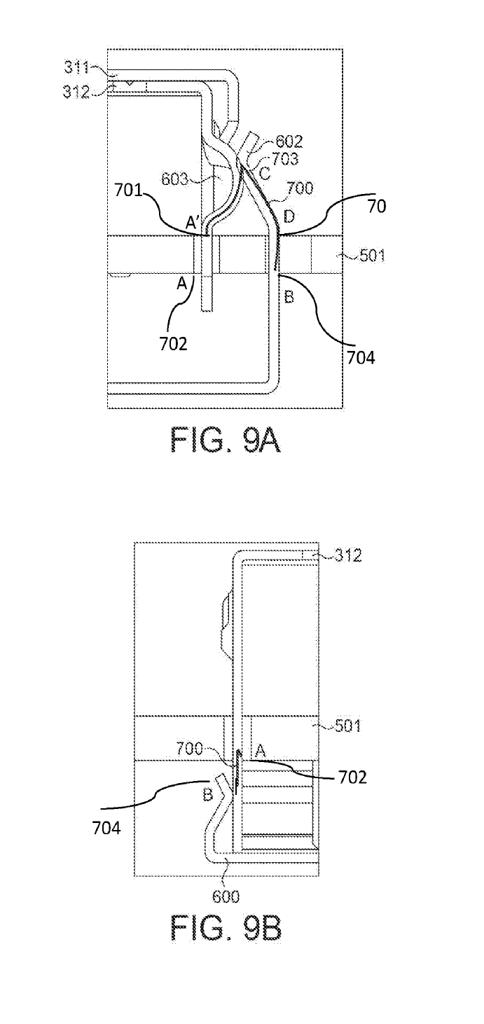

As explained above, in link with FIG. 15D, a center-to-center spacing 6040 of the extension elements 604 is needed to be kept less than 5.8 mm to guarantee an opening 6042 between two consecutive pins or feet is less than 5.26 mm. However, this threshold of 5.8 mm is a combination of a distance between consecutive pins plus an added ground length due to a ground path that may exist between the top and bottom shielding structures. The approximation that the ground reference for the shielding is the ground via connection to the circuit board is made for calculating the ground path. FIG. 9A illustrates on the cross section partial view already illustrated by FIG. 11A a ground path between the top shielding structure and the bottom shielding structures. The ground reference from the bottom shielding structure is a point B 704 on the bottom of the circuit board 501 where the extension element 604 extends through a hole 5010 of the circuit board. This point B is located in a hole 5010 of the circuit board without any electrical connection to the printed circuit board. In the particular embodiment illustrated by FIGS. 11A to 110 and 9A, the top shield goes at point A 702 through a hole 5012, which is a “plated-thru” soldered hole, of the printed circuit board (thus with an electrical connection).

Based on the additive nature of the ground lengths, the ground path 700 can be estimated by the dimension A-B corresponding to a path:
having a first end (locating at point A 702) at a point of contact between the extension element of top shielding structure with the bottom of the circuit board, then going to an intermediate point A′ 701 being a point of contact between the top shielding structure with the top of the circuit board (As both sides of the printed circuit board are going to have the same level, at an EMI standpoint, the distance between point AA′ does not need to be considered),
then going to a point of contact (locating at intermediate point C 703) between a contacting element 602 of the bottom shielding structure 600 and a contacting element 603 of the top shielding structure,
then going to an intermediate point D 701, right where the extension element 604 of the bottom shielding structure 600 goes through the circuit board 501,
then crossing the circuit board from point D and arriving at another end (locating at a point B 704 on the bottom of the circuit board 501

The A-B dimension is added for each feet to the foot to foot spacing X (element 6042 of FIG. 15D) to determine the effective spacing for RF shielding or the radiofrequency threshold (e.g. if the X+2 AB=10 mm, then the wavelength limit would be 100 mm).

FIGS. 12A, 12B and 12C illustrate a third embodiment, similar to the first and the second embodiment, except that the contacting elements 603 of the top shielding structure (that comprise ribs according to FIG. 10A) comprise bend out flanges 607 which protrude perpendicular to the lateral wall of the top shielding structure. Such an embodiment can permit a use of extension elements of the bottom shielding structure being even shorter than in the second embodiment, as illustrated by FIGS. 100, 110 and 12C.

In the illustrated embodiment, the bend out flanges 607 protrude from the shield of the top shielding structure but of course in other embodiment, it can protrude from the shield cover of the top shielding structure.

Depending upon embodiments, the bend out flange can have different shapes. For instance, in the illustrated embodiment of FIGS. 12A and 12B, the bend out flanges can be realized by cuts in the lateral wall of the shield of the top shielding structure, resulting in rectangular openings 3122 in the shield. Such an opening can have a vertical length 3124 of range from 0.1 to 0.5 mm (for instance 0.35 mm), compared to the extremity of the shield that is distal to the circuit board. The opening can have a horizontal length 3126 of range from 1 to 5 mm (for instance 3.0 mm). In another embodiment, the opening can have rounded edges for instance. As illustrated by FIG. 12A, at least one part of the lateral wall of the shield of the top shielding structure can present an alternate design of upper ribs and bend out flanges, one upper rib (intended to the assembly of the top shield and the top shield cover) being followed by zero or one bend out flange (intended to the assembly of the top shield and the bottom shielding structure), and vice-versa.

FIGS. 13A, 13B and 13C illustrate a fourth embodiment, similar to the first and the second embodiment, except that the contacting elements 603 of the top shielding structure are different. Indeed, in the illustrated embodiment, the contacting elements are located on the top shield cover 311. The top shield cover 311 is modified to have a bend out portion that extends horizontally outward from the top shield cover lateral wall portion and then downward, in a vertical plan closer than the lateral wall of the top shielding structure to the first series of clearance holes 5010 of circuit board (and perpendicular, and almost perpendicular, to the circuit board). In such an embodiment, the extension elements 602 of the bottom shielding structure can be kept almost perpendicular to the clearance holes 5010, thus permitting to use clearance holes 5010 of reduce dimensions. Such an embodiment does not result in openings in the top shield, thus permitting a better shielding.

In the particular embodiment illustrated, the bend out portion includes a bead 608 on a vertical portion. The spring clips 602 of the bottom shielding structure 600 contact the top shield cover by contacting the bead 608. The contact surface of the spring clips of the bottom shielding structure can have an interior surface contoured (such as being concaved), like the groove 6020 illustrated by FIGS. 13A, 13B and 13C for instance, to fit over the protruding bead 608.

Such a contoured surface can to be adapted to facilitate the insertion of the contacting element 602 of the bottom shielding structure on the bead 608 of the contacting element 603 of the top cover. In the illustrated embodiment, the groove 6020 does not extend to the extremity of the extension element, thus also acting as a retaining mean, in order to maintain the bead in the groove.

FIGS. 14A, 14B and 14C illustrate a fifth embodiment, similar to the second and third embodiment, except that the contacting elements 603 of the top shielding structure are formed by portions bending out of the shield cover of the top shielding structure. As illustrated, the bend out portions extends outward from the top shield cover lateral vertical wall portion at an acute angle with respect to the lateral vertical wall of the top shield cover and then the bend out portions bend inward downward. A part of a bend out portion constitutes a matching surface with a contacting element 602 of the bottom shielding structure. For instance, a part of the bend out portion can have a surface in a same plan as a matching surface of a contacting element 602 of the bottom shielding structure. A contacting element of the bottom shielding structure and a contacting element of the top shielding structure both act as spring finger, thus improving the contact between the two shielding structures.

The above detailed embodiments have been described in link with a bottom shielding structure having extension elements 604, extending though the circuit board 501 and comprising contacting elements 604 (like spring clips) that come in contact with contacting elements 603 of the top shielding structure. Of course, in variants, the top shielding structure can have extension elements 3120 extending though the circuit board 501 and comprising contacting elements (like spring clips) that come in contact with contacting elements of the bottom shielding structure. Other variants can be implemented.

For instance, FIGS. 15A, 15B, 15C, 15D, 15E and 9B, illustrate a sixth embodiment, constituting another variant where the top shielding structure have extension elements, extending through the circuit board and coming in contact with contacting elements 602 (like spring clips) of the bottom shielding structure.

As illustrated by FIG. 15D, the top shield of the top shielding structure 312 comprises at least one extension element (as the illustrated pins 615) adapted to extend through a clearance hole 5012 of the circuit board in order to be in contact with the bottom shielding structure and at least one support element (for instance support pins 616) adapted to engage with an aperture of the circuit board and then with a mating aperture of the bottom shielding structure (like the H-shaped slots or trap 3110 of the bottom shielding structure illustrated by FIGS. 15A and 15B) to help support and attach the bottom shielding structure with the circuit board (as illustrated by FIG. 15B). The support element and the extension element can have different dimensions, depending upon embodiments. Notably, the support element can be wider than the extension element. In some scenarios where the top shield is soldered to the printed circuit board after the assembly of the top shield with the bottom shielding structure, if just the pins 615 are used, the bottom shielding structure 600 tends to fall out, shift, or slide when the board moved or flipped during or before soldering. The engagement of the support pins which can be for instance at least 3 times wider than the pins 615, will engage the slots 3110.

The number of extensions elements and support elements van vary upon embodiments. Notably, the ratio between the number of extension elements and the number of support elements can vary. In the particular embodiment illustrated, there are at least three times as many pins 615 compared to the support pins 616. The wide support pins 616 can be positioned further inward toward central regions of the top shield than the pins 615. The slots 3110 behave as a locking mechanism to hold the bottom shielding structure in place so that the circuit board can be moved and worked on without the risk of the bottom shielding structure moving prior to soldering.

The extension element can protrude to the bottom of the circuit board. For instance, there can be a gap of 2.5 mm between an extremity of an extension element and the circuit board.

As illustrated by FIG. 15D, the top shield can comprise on its side at least one notch that the top shield cover can snap over. The top shield can also comprise a vacuum pickup. This vacuum can for instance be located on a central portion of the base of the top shield. Term base is used herein but it is to be understood that the base will be located on the upper part of the top shield once mounted on the circuit board). This base can comprise large openings as illustrated.

At least some embodiments illustrated by FIGS. 15A to 15E and 9B attempt to reduce the ground length between two extension elements of the top shield. FIG. 9B illustrates, by the dimension A-B on the cross section partial view of FIG. 15E, a ground path between the top shielding structure and the bottom shielding structure. Point A is located on the bottom of the circuit board. It is one end of a plated-thru hole, being a hole 5012 of the printed circuit board. Point B is the point of contact between a contacting element 602 of the bottom shielding structure and a contacting element of the top shield. In the embodiment illustrated by FIG. 9A, the ground reference B 704 of the bottom shielding structure is at a very short distance from the point of contact A 702 between the extension element of the top shield and the bottom of the circuit board. Any EMI radiating from the bottom of the circuit board would be referenced to point A. The length of the path AB of FIG. 9B is much shorter than the length of path AB of FIG. 9A. As explained above in link with FIGS. 11A, 11B, 110 and 9A, the distance A to B needs to be taken into account for fulfilling the wavelength limit. Reducing the distance A-B can permit to increase the upper limit of the spacing between the extension elements of the bottom shielding structure. This can thus ease the production of the printed circuit board assembly of the present disclosure.

FIGS. 16A, 16B, and 16C illustrate a seventh embodiment, constituting another variant of the first and second embodiment. As illustrated by FIGS. 16B and 16C, extension elements 604 of the bottom shielding structure comprises spring clips 602 smaller but more bent that in the first and second embodiment. Interior contact points of the spring clips of the bottom shielding structure engage interior ribs or indents of the top shield 312 of the top shielding structure. FIG. 16A illustrates the opposite side, compare to the side illustrated by FIG. 16C, of the lateral wall of the top shield, and shows the extension elements 3120 of the top shield 312 extending through the second series of holes 5012 of the circuit board 501.

FIGS. 17A, 17B, 17C, 17D and 17E, illustrate an eight embodiment, where the bottom shielding structure is similar to one of the first, second and seventh embodiments and where the top shielding structure is modified. The shield cover 311 of the top shielding structure can be similar to the one already described in link the above embodiments, and thus is not illustrated. In the eight embodiment, the lateral walls of the top shield of the top shielding structure have a bent wall design in which, from a top outward bent wall portion of the lateral wall, a first (almost vertically) inward bent wall portion extends downward toward the circuit board. Then, from this first inward bent wall portion, a second wall portion extends inward from the first inward bent wall portion. In some particular embodiment, as in the illustrated embodiments, the second portion extends horizontally inward. The gap 3128 between the circuit board and the second portion can differ upon embodiments. Notably, it can be in a range of 0.5 to 1 mm (for instance 0.7 mm).

Extension elements (pins for instance) 3120 extend downward from the edge of the second inward bent portion and go through the second series of holes 5012 of the circuit board. Depending upon embodiments, an extension element 3120 can protrude or not to the opposite side of the circuit board.

Embodiments, where the extension elements extend perpendicularly (or almost perpendicularly) through the circuit board (like the pins 3120 of the top shield in the illustrated embodiment) can permit to ease and secure insertion of an extension element inside a hole of the circuit board. Indeed, in some scenarios, a hole can have sharp and fragile edge, making it difficult to insert a bent extension element.

In some embodiments, the top outward wall portion can be adapted to be in contact with the extension elements of the bottom shielding structure. In other embodiments, the top outward bent portion can further comprise contact elements. For instance, the top outward bent wall portion can comprise lower ribs or indents adapted to be in contact with the spring clips of the bottom shielding structure.

FIGS. 18A, 18B, 18C and 18D illustrate a ninth embodiment, constituting a variant of the first embodiment described. In this ninth embodiment, the first and second series of holes of the circuit board present an alternate design, where one hole 5010 of the first series (intended for a spring clip of the bottom shielding structure, that can extend through) is adjacent with a hole 5012 of the second series (intended for a pin of the top shield, that can extend through), and vice-versa.

Top shield of the top shielding structure have extension elements, extending though the circuit board. Depending upon embodiments, the extension elements 3120 can protrude or not from the circuit board.

In the illustrated embodiment, both series of holes 5010, 5012 are aligned (or almost aligned) together, forming a single parallel dotted line (being formed alternatively by a hole of the first series and a hole of the second series). Such an embodiment can help to obtain a printed circuit board assembly with distance between extension elements fulfilling the minimum distance required for avoiding the escape of the waves. In the illustrated embodiment, the distance between pins to be considered is the distance between an extension element of the top shielding structure and an extension element of the bottom shielding structure (anot between extension elements of a same shielding structure).

In the illustrated embodiment of FIG. 18D, the top shielding structure is assembled by engaging the shield cover 311 of the top shielding structure over a single rib 334 protruding along the lateral wall of the shield 312.

Several embodiments have been described above. Most of the embodiments describes contact elements of the top or bottom shielding structure being of a given type (like bead, flanges, groove . . . ). The current principles also apply to embodiments where the top and/or bottom shielding structure comprises different types of contact elements, adapted to cooperate together to make a mechanical and electrical contact point between the top shielding structure and/or the bottom shielding structure.

The current principles are applicable to top and/or bottom shielding structure comprising at least one single height shield and/or at least one multiple height shield.

The current principles include that the shield over the circuit board and the shield below the circuit board contact each other. The contact can be that the pins, feet or extensions that protrude through the holes in the circuit board contact components of the opposite shield. The components of the opposite shield can be the shield cover or bend out portions.

The principles can include electronic devices with a bottom shielding structure having top plan view perimeter being outside the top plan view perimeter of the top shielding structure, or vice-versa.

The current principles can include that electronic components and/or electric traces are on the top surface of the circuit board and surrounded by the top shielding structure, and/or electronic components and/or electric traces are on the bottom surface of the circuit board and surrounded by the bottom shielding structure.

The top and/or bottom shielding structure can have vertical outer side walls wherein corresponding vertical outer side walls of the top shielding structure can be parallel to corresponding vertical outer side walls of the bottom shielding structure. Of course, the present disclosure also comprises embodiments similar to the embodiment described where the first side of the circuit board is the bottom side of the circuit board and the second side of the circuit board is the top side of the circuit board. Notably, term “top” and “bottom” can be understood herein according a main side of the circuit board (being referred to as the “top” side), as it will be obvious for the one skilled in the art, as well as according to the position of the printed circuit board once mounted in an electronic device (thus defining a top and bottom side as it will be obvious for the one of ordinary skills.

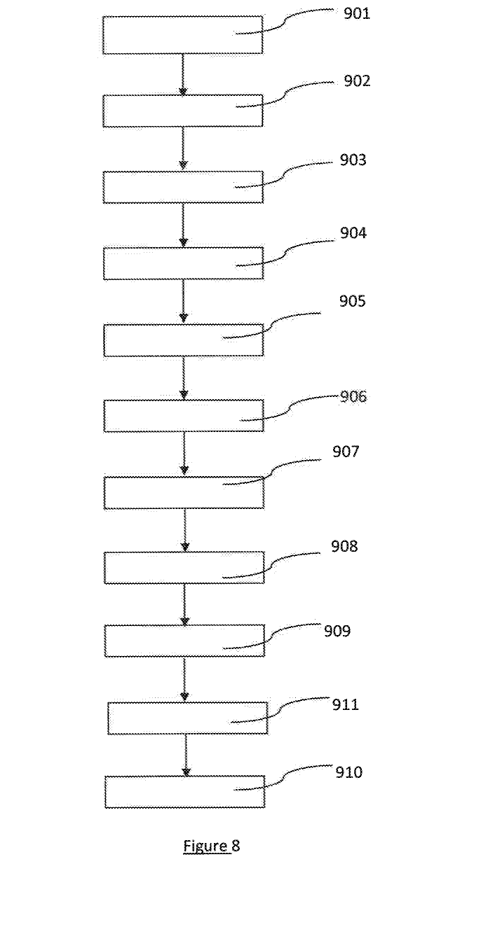

An aspect of the principles which can be used with the current principle includes the method in which an electronic device is constructed. The method is described in FIG. 8 which can begin with providing in step 901 a circuit board 501 having holes 521 and having electronic components on a first side (for instance a top side) of the circuit board. Next, in step 902, a first radiofrequency shield (for instance a radiofrequency top shield 312) is formed or provided to surround and provide radiofrequency shielding to the electronic components 504 on the first side of the circuit board. The expressions “to provide” and “providing” in relation to the steps 901 and 902 and in other features that involve components are intended to include making the component, acquiring, or preparing the component for installation. The radiofrequency top shield can have pins 502 and a contact edge 510 from which extension elements (like pins 502) extend. The pins are positioned to correspond to the holes and can extend from the contact edge a vertical dimension that is between 50 to 90% of a thickness of the printed circuit board. In step 903, at least an interior region of the holes is plated with solder. In step 904, the pins of the radiofrequency top shield are aligned with the holes of the circuit board. In step 905, the radiofrequency top shield is reflow-soldered onto the circuit board in which the pins are engaged with the holes by the solder. In step 906, the pins are inspected to ensure the pins are properly soldered and the electronic components are inspected to ensure that the electronic components are securely attached and/or properly functioning. In step 907, any pins and/or electronic components are touched up by resoldering if more soldering is needed. In step 908, a shield cover 311 is provided or formed and the shield cover is placed on the radiofrequency top shield 312. The top shield and the top shield cover constitute a top shielding structure. In step 909, if desired or otherwise designed into the device, another electronic component such as a smart card assembly having a smart card outline (representing the perimeter of the smart card assembly) is attached on a second side (for instance bottom side) of the circuit board such that the smart card outline laterally overlaps at least a portion of the radiofrequency shield 312. In step 911, a second radiofrequency shield (for instance a radiofrequency bottom shield), located on the second side of the circuit board (as illustrated by FIGS. 10A to 18D) is mounted with the top shielding structure. A bottom shield cover, which is located on the bottom shield, thus forming a bottom shielding structure. No soldering is applied between the bottom shielding structure and the printed circuit board. Indeed, at least one first contacting element 602 of the bottom shield makes a mechanical and electrical contact between the top shielding structure and the bottom shielding structure in a contact region entirely located outside the holes of the circuit board.

In step 910, a chassis or the housing of the electronic device that contains the circuit board and components thereon is closed to complete fabrication of the electronic device.

An aspect of the principles which can be used with the current principle includes the method in which a circuit board assembly is constructed. In some embodiments, such a method can be described similarly to the method illustrated by FIG. 8, except than step 910 is omitted.

As it will be obvious for the one skilled in the art, for both methods, the ordering of the steps can differ upon embodiments.

1. A printed circuit board assembly comprising:
a printed circuit board;
a first shielding structure located on a first surface of the printed circuit board and having at least one first extension element extending from said first shielding structure and through a first hole in the printed circuit board; and
a second shielding structure located on a second surface of the printed circuit board;
wherein:
at least one first contact element of said at least one first extension element makes a mechanical and electrical contact between the first shielding structure and the second shielding structure in a contact region entirely located outside the first hole from which said at least one first extension element is extending through;
said second shielding structure comprises a shield and a shield cover; and
the mechanical and electrical contact is made by said at least one first contact element and at least one second contact element of the shield cover of said second shielding structure.

2. The printed circuit board assembly of claim 1 wherein said second shielding structure has at least one second extension element extending from said second shielding structure and through a second hole in the printed circuit board.

3. The printed circuit board assembly of claim 2 wherein the first hole and the second hole are different.

4. The printed circuit board assembly of claim 3 wherein at least one adjacent hole of a second hole from which one of said at least second extension element is extending through is a first hole from which one of said at least one first extension element is extending through.

5. The printed circuit board assembly of claim 1 wherein said first shielding structure comprises a shield and a shield cover.

6. The printed circuit board assembly of claim 5 wherein said at least one first and/or second extension element is extending from the shield of the first and/or second shielding structure.

7-8. (canceled)

9. The printed circuit board assembly of claim 1 wherein said at least one second contact element comprises at least one protruding element.

10. The printed circuit board assembly of claim 9, wherein a contact surface of the at least one first contact element has an interior surface contoured to fit over one of said at least one protruding element.

11. The printed circuit board assembly of claim 1 wherein said at least one first extension element, said at least one second extension element, said at least one first contact element and/or said at least one second contact element comprise at least one element belonging to a group that includes:
a finger;
a foot;
a spring clip;
a spring finger;
a pin;
a rib;
a indent;
a flange;
a wall;
a bead; and
a combination thereof.

12. The printed circuit board assembly of claim 1 wherein the first and/or second shielding structure has at least one anchoring element for anchoring said first and/or second shielding structure to said printed circuit board.

13. The printed circuit board assembly of claim 1 wherein an electrical connection between said first shielding structure and said printed circuit board is made at said first hole.

14. The printed circuit board assembly of claim 1 wherein said first hole is a plated-thru hole.

15. The printed circuit board assembly of claim 2 wherein an electrical connection between said second shielding structure and said printed circuit board is made at said second hole.

16. (canceled)

17. The printed circuit board assembly of claim 1 wherein no electrical connection is made at said first hole between said first shielding structure and said printed circuit board.

18. An electronic device having:
a printed circuit board;
a first shielding structure located on a first surface of the printed circuit board and having at least one first extension element extending from said first shielding structure and through a first hole in the printed circuit board,
a second shielding structure located on a second surface of the printed circuit board;
wherein:
at least one first contact element of said at least one first extension element makes a mechanical and electrical contact between the first shielding structure and the second shielding structure in a contact region of said electronic device, said contact region being entirely located outside the first hole from which said at least one first extension element is extending through;
said second shielding structure comprises a shield and a shield cover; and
the mechanical and electrical contact is made by said at least one first contact element and at least one second contact element of the shield cover of said second shielding structure.

19. The electronic device of claim 18 characterized in that said electronic device is a set top box.

20. A method for construing a printed circuit board assembly, said method comprising:
mounting a first shielding structure on a first surface of a printed circuit board, said first shielding structure having at least one first extension element extending from said first shielding structure and through a first hole in the printed circuit board,
mounting a second shielding structure on a second surface of the printed circuit board,
said second shielding structure comprising a shield and a shield cover; and
at least one first contact element of said at least one first extension element making a mechanical and electrical contact between the first shielding structure and the second shielding structure in a contact region of said electronic device, said contact region being entirely located outside the first hole from which said at least one first extension element is extending through, the mechanical and electrical contact being made by said at least one first contact element and at least one second contact element of the shield cover of said second shielding structure.

21. (canceled)
